(19) United States
(12) Patent Application Publication
(10) Pub. No.: US 2024/0203425 A1
(43) Pub. Date: Jun. 20, 2024

(54) EFFECTIVE EXTRACTION OF VOICE BIO, ACOUSTIC AND LINGUISTIC MARKERS FROM AN AUDIO SIGNAL FOR SPEAKER IDENTIFICATION

(71) Applicant: YOBE, INC., St. James, NY (US)

(72) Inventor: Kenneth SUTTON, St. James, NY (US)

(21) Appl. No.: 18/540,549

(22) Filed: Dec. 14, 2023

Related U.S. Application Data
(60) Provisional application No. 63/432,495, filed on Dec. 14, 2022.

(51) Int. Cl. G10L 17/04; G10L 21/0208; G10L 21/028; G10L 25/30; G10L 25/84; H03M 1/12

(52) U.S. Cl. CPC G10L 17/04; G10L 21/0208; G10L 21/028; G10L 25/30; G10L 25/84; H03M 1/12

(57) ABSTRACT

The disclosure generally relates to systems and methods for using audio biometrics to isolate a target audio signal from a plurality of audio signals, the methods include determining, isolating, and differentiating metadata associated with the target audio signal and removing or suppressing audio metadata not associated with the target audio signal.

### RELATED APPLICATION

This application claims the benefit of U.S. Provisional Application No. 63/432,495 filed on Dec. 14, 2022, the contents of which are incorporated herein by reference in their entirety.

### TECHNICAL FIELD

The present disclosure relates generally to extracting and differentiating audio content. In particular, some embodiments are directed towards systems and methods for isolating, differentiating, and extracting audio signals using biometrics.

### BACKGROUND

Since the advent of audio processing, audio engineers have strived to efficiently and effectively extract target audio signals (e.g., a single specific audio signal) from a plurality of audio signals (e.g., a general grouping of sound). Historically, audio engineers have used various conventional methods to extract target audio signals. One such method can include filtering audio with a filter device (hereafter referred to as “filters”). Filters can be useful for removing certain unwanted frequency bands (i.e., noise). For example, bandpass filters can be used to pass desired frequency bands and suppress unwanted frequency bands, while stop band filters can be used to notch out desired frequency bands from the unwanted frequency bands.

However, filters are often insufficient in environments where there is a high level of background noise or multiple speakers. Conventionally, these environments require computationally intensive post-production methods to filter out unwanted or non-targeted audio signals. These post-production methods produce long latency periods and necessitate significant bandwidth as large amounts of data are sent to and from the servers for processing. Other methods, such as directional microphones that can “focus” on an individual speaker and direct the microphone away from unwanted sources of noise are not practical since they require sophisticated and proactive planning to operate and track a particular speaker, thus limiting the efficacy of such microphones to controlled situations. Better systems are needed.

### BRIEF SUMMARY

The systems and methods herein disclose ways in which audio signals can be isolated, differentiated, and effectively extracted to enhance user functionality and operability for human to machine voice interface applications.

In various embodiments, the present disclosure discusses a method for voice isolation. The method may include receiving a plurality of audio signals, where the audio signals include spoken voice or a homogenous voice data group. A homogenous voice data group may be a grouping of audio signals that are identifiable to a particular speaker. The method may further include extracting a first set of acoustic characteristics from each of the plurality of audio signals and then associating a first set of metadata to the extracted first set of acoustic characteristics. In this context, acoustic characteristics may include, for example, frequency, pitch, loudness, vocal timbre, vocal phenomes, formants, spectral peaks, modality, breath, and rhythm identifiable to a speaker's voice (other acoustic characteristics may be included, as discussed below), and metadata may be various forms of data that provide information about the acoustic characteristics, for example, metadata relating to loudness may include a numerical indication of decibel range found in a homogenous voice data group. The method may also include creating a voice biometric profile for the homogenous voice data group, where the voice biometric profile includes the first set of metadata associated with the first set of acoustic characteristics of the audio signal associated with the homogenous voice data group. Further, the method may include identifying a target audio signal from the plurality of audio signals based on the voice biometric profile, and isolating the target audio signal from the plurality of audio signals by enhancing audio signals with, or associated with, the first set of acoustic characteristics, and suppressing audio signals not associated with the first set of acoustic characteristics.

In further embodiments, the method may include receiving the plurality of audio signals including a second and third homogenous voice data group, extracting a second or third set of acoustic characteristics from the plurality of audio signals, associating a second or third set of metadata with the second or third set of acoustic characteristics, and creating a second or third voice biometric profile for the second or third homogenous voice data groups, wherein the second or third voice biometric profiles comprise the second or third set of metadata associated with the second or third voice data group. In further embodiments, the method may include differentiating the second and third voice biometric profiles by comparing the first, second, and third sets of metadata, and isolating audio signals associated with the first voice biometric profile.

In further embodiments, the voice biometric profile may uniquely identify a target speaker. In further embodiments, the method may further include converting each audio signal of the plurality of audio signals to a digital signal via an analog-to-digital converter, where the digital signal may include acoustic characteristics associated with each of the plurality of audio signals. In further embodiments, the method may include suppressing audio signals not associated with the voice biometric profile by filtering audio signals outside of the voice biometric profile. In further embodiments, the target audio may be isolated from the plurality of audio signals by machine learning methods stored in a memory of a user device where the machine learning methods may be configured to isolate metadata associated with target audio signal.

In various embodiments, the present disclosure discusses a system for voice differentiation. The system may include an audio receiver configured to receive an analog audio signal, an analog-to-digital converter configured to convert the analog audio signal received by the audio receiver to a digital audio signal, and a biometric computing component, including a processor and a non-transitory computer readable medium with computer executable instructions embedded thereon. The computer executable instructions may include extracting or associating acoustic characteristics with the digital audio signal; associating or relating metadata to the extracted acoustic characteristics; grouping the metadata into voice biometric profiles if a first homogenous voice data group is detected in the digital audio signal; differentiating the first voice biometric profiles from a second voice biometric profile if two homogenous voice data groups are detected in the digital audio signal; and suppressing audio signals not associated with the first voice biometric profile.

In further embodiments, the two homogeneous voice data groups may include a first homogenous voice data group and a second homogenous voice data group. In further embodiments, the system may include a third voice biometric profile, where if three homogenous voice data groups are detected in the digital audio signal, where the three homogenous voice data groups may include a first homogenous voice data group, a second homogenous voice data group, and a third homogenous voice data group, where the system may differentiate the first biometric profile from the second and third biometric profiles and suppress audio associated with the second and third biometric profiles. In further embodiments, the acoustic characteristics may be associated with the digital audio signal at discrete audio frames. In further embodiments, the computer executable instructions may further be configured to cause the processor to isolate the metadata associated with a single speaker to create a voice biometric profile. In further embodiments, the computer executable instructions may further be configured to isolate the metadata associated with a target audio signal via their voice biometric profile from a plurality of audio signals. In further embodiments, the computer executable instructions may further be configured to cause the processor to identify a target speaker based on a grouping of acoustic characteristics. In further embodiments, the computer executable instructions may further be configured to filter metadata not associated with a target audio signal. In further embodiments, the computer executable instructions may further be configured to cause the processor to enhance an audio signal associated with a target speaker by differentiating audio associated with the voice biometric profile of the target speaker from audio associated with voice biometric profiles of non-target speakers. In further embodiments, the system may further include a transceiver communicatively coupled to a server, wherein the server includes a plurality of known voice biometric profiles, and wherein the system for voice differentiation identifies a target speaker by transmitting a voice biometric profile to the server, matches the transmitted voice biometric profile with a known voice biometric profile, and transmits an identification of the target speaker to the system for voice differentiation from the server.

In various embodiments, the present disclosure discusses a method for differentiating a target audio signal from a plurality of audio signals. The method may include receiving a plurality of audio signals from an audio input device; extracting acoustic characteristics from each audio signal of the plurality of audio signals; associating each acoustic characteristic to a set of metadata; grouping each set of metadata with other sets of metadata representative of the target audio signal; and differentiating metadata associated with the target audio signal from metadata associated with remaining plurality of audio signals.

In further embodiments, the target audio signal may include a homogenous voice data group, wherein the homogenous voice data group may further include acoustic characteristics that can be extracted from the audio signal, and wherein the acoustic characteristics may be associated with a set of metadata that is grouped into a voice biometric profile that uniquely identifies a target speaker. In further embodiments, the plurality of audio signals may include multiple homogenous voice data groups, wherein each homogenous voice data group includes unique and different acoustic characteristics that can be represented by metadata, and wherein the acoustic characteristics associated with each homogenous voice data group may be grouped into a voice biometric profile that identifies each speaker as a different person speaking. In further embodiments, the method may include suppressing audio signals not associated with the target audio signal by filtering audio signals outside of the target audio signal. In further embodiments, the method may include isolating from the plurality of audio signals.

Other features and aspects of the invention will become apparent from the following detailed description, taken in conjunction with the accompanying drawings, which illustrate, by way of example, the features in accordance with embodiments of the invention. The summary is not intended to limit the scope of the invention, which is defined solely by the claims attached hereto.

### BRIEF DESCRIPTION OF THE DRAWINGS

The present disclosure, in accordance with various embodiments, is described in detail with reference to the following figures. The drawings are provided for purposes of illustration only and merely depict typical or example embodiments of the invention. The drawings are provided to facilitate the reader's understanding of the disclosure and shall not be considered limiting of the breadth, scope, or applicability of the invention. It should be noted that for clarity and ease of illustration these drawings are not necessarily made to scale.

FIG. 1 depicts an illustration of an example environment in which the effective audio extraction system may be applied, according to various embodiments disclosed herein.

FIG. 2 depicts an illustration of an example network environment, according to various embodiments disclosed herein.

FIG. 3 depicts a diagram illustrating components of an example user device in which portions of the system and methods disclosed herein may be applied, according to various embodiments disclosed herein.

FIG. 4 depicts an illustration of an example method of implementing the audio extraction system, according to various embodiments disclosed herein.

FIG. 5 depicts an illustration of an example method for extracting audio, according to various embodiments disclosed herein.

FIG. 6 is an illustration of an example environment in which the effective audio extraction system may be applied, according to various embodiments disclosed herein.

FIG. 7 is an example graphical illustration of audio signals separated by audio frame, according to various embodiments disclosed herein.

FIG. 8 illustrates an example computing module that may be used in implementing various features of embodiments of the systems and methods described herein.

The figures are not intended to be exhaustive or to limit the disclosure to the precise form disclosed. It should be understood that the disclosure can be practiced with modification and alteration, and that the disclosure be limited only by the claims and the equivalents thereof.

### DETAILED DESCRIPTION

Systems and methods for isolating, differentiating, and identifying a target audio signal for effective extraction from a plurality of audio signals are disclosed herein. By extracting acoustic characteristics from audio signals, and then associating metadata to the extracted acoustic characteristics, the systems and methods discussed herein can detect, differentiate, and/or isolate metadata associated with a target audio signal, from metadata associated with a plurality of audio signals. By detecting, differentiating, and/or isolating metadata associated with target audio signals, the systems and methods discussed herein can be used to effectively extract target audio signals without the requirement for burdensome filters (e.g., passband filters, notch filters, etc.), proactive and sophisticated directional microphone techniques, or inefficient post production techniques as applied in some conventional audio isolation and/or extraction techniques.

Audio signals, generally, may be a representation of sound in an electronic form, typically as variations in voltage over time. Sound waves, which may be variations in air pressure, can be converted into electrical signals via a microphone. These electrical signals, i.e., audio signals, can then be processed, transmitted, and ultimately converted back into sound waves by speakers. These audio signals may carry information about the amplitude, frequency, and/or phase of the original sound, allowing it to be reproduced in an audible form. Audio signals can be fundamental in various applications, including music production, telecommunications, surveillance, broadcasting, and multimedia.

In addition to the electrical information audio signals may carry, audio signals may also include acoustic characteristics. These acoustic characteristics may include features, traits, and/or qualities of audio signals. Acoustic characteristics can also include voice and linguistic markers within the audio signals. For example, an audio signal may carry information relating to the frequency, pitch, loudness, vocal timbre, vocal phenomes, formants, spectral peaks, modality, breath, and rhythm of a speaker's voice (merely to name a few, as this is a non-exhaustive list of potential acoustic characteristics that can be extracted from an audio signal).

As discussed further herein, the acoustic characteristics extractable from an audio signal can be used to determine, identify/differentiate, and separate a target audio signal or homogenous voice data group from a plurality of audio signals. For example, a device or method may function around the notion that each individual may have a unique voice print (including various specific acoustic characteristics), that each unique voice print can present as a homogenous voice data group, and that sophisticated listening devices may recognize that voice print (by matching known acoustic characteristics stored in a profile to the homogenous voice data group in the audio signal including the same or similar acoustic characteristics), as well as be able to differentiate one unique voice print from another unique voice print (or a first homogenous voice data group from a second homogenous voice data group). Identification and/or authentication of the voice print may hereafter be referred to as “biometrics” or “voice biometrics.” Voice biometrics, including acoustic and linguistic markers, may allow for speaker identification (and contextual awareness) to enhance user functionality and operability for human to machine voice interface applications.

A homogenous voice data group may be an grouping of audio signals identifiable to a unique voice print. A unique voice print may be the set of acoustic characteristics found in a person's speaking voice when recorded with an audio recording device (e.g., a microphone, etc.) On the other hand, a voice biometric profile may be a stored profile of known acoustic characteristics found in a person's voice. In other words, voice biometrics may be a version of an individual's unique voice print that is stored on a device. Voice biometrics may then be used to match a person's voice biometric profile to a target audio signal or homogenous voice data group including their unique voice print.

The voice biometric profile may store full versions of the acoustic characteristics representative of the individual's unique voice print, for example, graphical data representative of formant, or may store metadata representative of the particular acoustic characteristics of a particular individual's voice profile, for example, numerical representations of the broad peak found in the formant graph (but not the entire graph or graphical data set). In other words, to reduce the amount of memory required to store a voice profile and reduce the amount of information transmitted to identity a voice biometric profile against an audio signal or homogenous voice data group, a voice biometric profile may be stored as a set of metadata representative of the specific acoustic characteristics indicative of a person's speaking voice (i.e., their unique voice print heard as a homogenous voice data group). Although other devices and methods have attempted to use biometrics to determine, isolate, and extract a target audio signal, conventional methods have shown to be impractical in multi-signal environments where they could be more useful (e.g., for use with large groups in a crowded space, such as a cocktail party).

As discussed further herein, detected, determined, or extracted acoustic characteristics of an audio signal can be used to determine the voice biometric profile associated with an audio signal or homogenous voice data group for biometric identification, i.e., identifying a person speaking based on their unique voice print or homogenous voice data group or creating an “unknown person profile,” if the acoustic characteristics extracted from the audio signal do not match with a known voice biometric profile. These acoustic characteristic can also include, for example, the fullness of a sound event, the length of a sound event, and the sustain qualities in a sound event, in addition to the previously mentioned acoustic characteristics. For example, a sustained sound event can be used as a factor to determine a first speaker from a plurality of speakers, where the first speaker may be the target speaker.

As described in further detail throughout, the target audio signal or homogenous voice data group can be isolated and extracted using the techniques presented herein. In various analog to digital signal processing applications, an analog signal may be received by a single or multichannel device (e.g., an analog to digital converter (ADC)) and converted to a digital signal. The digital signal may include data and associated metadata pointing to, or representative of, said data. The metadata can then be used to determine, isolate, differentiate, and extract the target audio signal.

In various embodiments, the metadata associated with acoustic characteristics extracted from an audio signal may be analyzed on a user device to enhance human to machine voice functionality by extracting the target audio signal, differentiating a person speaking (or a group of people speaking) from another person speaking (or another group of people speaking), and identifying the person speaking. Analysis of audio signals, or metadata representative of audio signals, on a user device is hereafter referred to as “on edge” analysis (e.g., signal processing on a device that is local to the user and/or that is located on the edge of a network, as opposed to being transmitted via the network to a server or processor external to the user device). As described in further detail herein, user devices may include cellular telephones, smart phones, MP3 players and other media players, tablet computing devices, laptop and notebook computers, personal computers, two-way radios, hearing aids and assisted listening devices, and other devices for communicating, receiving, or playing audio content. In some configurations, the user device may include a digital kiosk or similar computer terminal featuring specialized hardware and software that provides access to information and applications for communication, commerce, entertainment or education. For example, a fast-food restaurant's food ordering kiosk. In such an example, the food ordering kiosk may first listen for the target audio signal (i.e., the speaker attempting to order food), then identify the voice biometric profile of the target audio signal, and then isolate the identified target audio signal by continuing confirmation of a match between the now expected voice biometric profile (the one previously identified) and the continuing input of the speaker at the kiosk. This isolation can reduce the amount of noise or other (non-target) speakers overheard by the microphones on the kiosk, allowing the kiosk to more accurately detect the intended voice input.

“On edge” analysis of audio signals may include various processing operations that may be performed on a user device. These various processing operations can include, but are not limited to, signal processing. For example, the user device can host a software application (hereafter referred to as “an app”) installed on the device. The user device can also display a customized website using a web browser installed on the device. In embodiments, the various processing operations may be performed in full or in part on a biometric computing component. As described further herein, the biometric computing component can perform voice identification, differentiation, and recognition of a target audio signal (among other processes). For example, the biometric computing component may be able to differentiate the voice of a speaker conversing with a kiosk from various speakers occupying generally the same area.

Unlike conventional methods of signal processing, the system and methods proposed herein provide for audio signal processing “on edge,” thereby reducing the need for processing audio signals and associated digital signals at a remote sever. Processing audio signals via a remote server can be limited by the availability of bandwidth and latency. Therefore, by processing audio signals at the user device or “on edge,” the system and methods discussed herein may decrease the overhead associated with transferring data to and from a remote server, thereby improving audio signal processing efficiency and quality.

In various embodiments, the present disclosure may provide an effective voice analysis and audio extraction system on edge. The audio extraction system may comprise a biometric component configured to extract or differentiate the target audio signal from a plurality of audio signals. The biometric component can include software downloaded to and stored on a user device. The software may include instructions stored in memory on the user device for machine learning (ML) methods to analyze various acoustic characteristics of the received audio signal. For example, the instructions may include ML methods configured to isolate metadata associated with a specific characteristic extracted from the audio signal. In such an example, the metadata may point to, or be reflective of, digital data associated with a specific audio signal.

In further embodiments, the present disclosure may provide for on edge detection of target audio signal direction and distance. In such embodiments, the user device may include an early auditory recognition (EAR) component configured to determine a direction and distance of the target audio signal.

In further embodiments, the disclosed systems and methods may be used when multiple audio signals are present (for example, when multiple people are speaking) to differentiate a target speaker or target audio signal, for the group of speakers or audio signals. For example, recorded audio from a room with two people may be played, and the present disclosure may be able to utilize acoustic characteristics identified from the recorded audio to differentiate one speaker from another. This may occur without prior knowledge of the speakers, i.e., without having a voice or speaker database that the recorded audio is compared against, or if the speaker is not known in the database and is thus an unknown person profile. In other words, the present disclosure may extract from audio signals, acoustic characteristics related to the audio signals, then associate the acoustic characteristics to metadata representative of the acoustic characteristics, and then differentiate speakers based on an analysis of the metadata on edge.

In even further embodiments, the present disclosure may assess audio signals by frame. An audio frame may be a brief period of time that audio is captured during, for example 100-130 milliseconds (ms), which acoustic characteristics can be attached to. In other words, a first audio frame may be from the initiation of the audio signal to time 100 ms, this audio frame may have various acoustic characteristics that are related to a first set of metadata. Then, a second audio frame from 101 ms to 200 ms, may have different acoustic characteristics that are related to a second set of metadata. This may repeat until the nth iteration of audio frame and set of metadata. Each frame of audio may be associated with a set of metadata.

The present disclosure may use these frames and their associated metadata to make assumptions about audio signals in each frame, and then use surrounding audio frames to confirm or adjust the assumptions of the frame it is being compared to. For example, if a first audio frame has acoustic characteristics indicative of two people speaking (i.e., two different pitches of voice or two different voice biometric profiles), the frame one assumption is that two different people are speaking. This can then be confirmed by comparing the first frame to the following ten frames, during which various other metadata can be compared to determine if the assumption of two voices is still accurate (i.e., cadence, frequency, sustain, etc. are all representative of two speakers). By comparing the subsequent audio frames against the primary frame, a confidence score can be created based on the initial assumption. If the confidence score reaches a threshold value, an indication can be presented on the user device. Audio frames can be compared against frames that come before (adjustments to the assumption) or after (assumptions about what's to come) the primary frame to improve the confidence score. The primary frame can be dynamically changing such that each audio frame is the primary frame and compared to surrounding frames (i.e., each frame is viewed in light of other frames and changes when reviewing each audio frame) or the primary frame may be updated with a fixed iteration of frames (i.e., every tenth frame is considered a primary frame and compared to the surrounding nine frames).

By viewing an auditory environment (i.e., the environment which produces the audio signal) in audio frames, as described, abrupt changes to the audio environment can be accounted for more quickly. For example, if a third person enters the room with the previously mentioned duo at the same time as an ambulance passes by, the metadata associated with the audio frame upon the two additions of audio signal can provide for new assumptions about the auditory environment. Here, it would be that an additional speaker entered the auditory environment and a noise that should be removed or suppressed entered the auditory environment. This updated assumption can quickly be accounted for as the audio frames may be analyzed on edge and can dynamically adjust parameters based on the changing auditory environment. For example, the voice biometric profile can be retrieved from a server to identify the third speaker, while the ambulance noise is muted in the background.

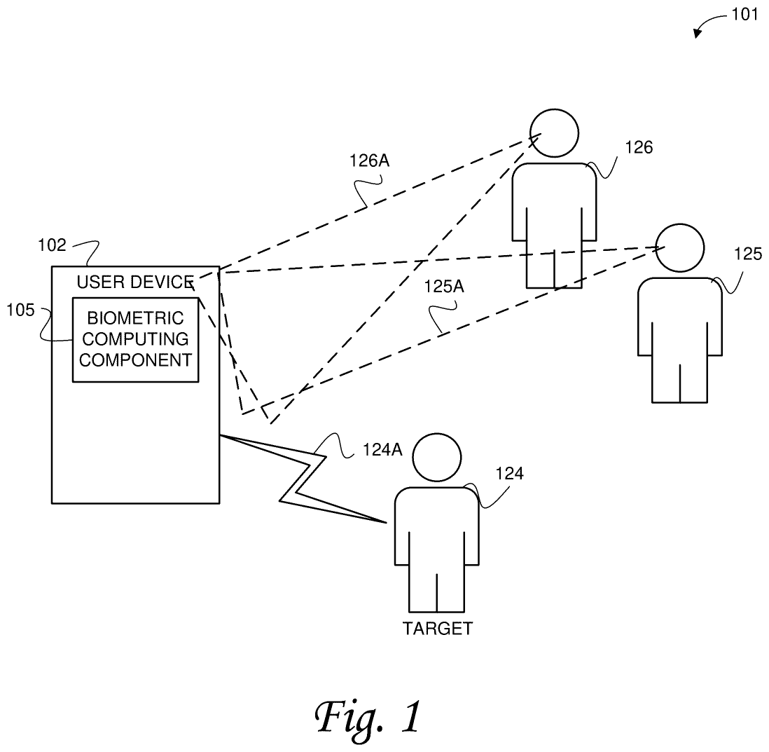

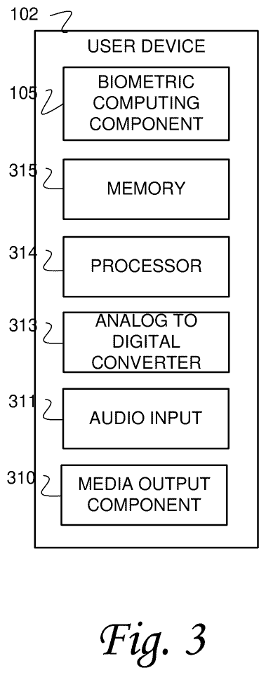

With respect to the figures, FIG. 1 depicts an illustration of an example environment 101 in which the effective audio extraction system may be applied, according to various embodiments. The effective audio extraction system 100 may include a user device 102 comprising a biometric computing component 105 for analyzing, detecting, extracting, or determining acoustic characteristics of audio signals. The biometric computing component 105 may be configured to receive audio input data (e.g., audio input 311 of FIG. 3). For example, in one configuration, the biometric computing component 105 may be configured to monitor individual speakers in a multi-speaker setting. By monitoring each audio signal in a multi-signal environment, the biometric computing component 105 can determine and isolate a target audio signal associated with a target speaker (i.e., an individual speaker). Moreover, by monitoring each audio signal in a multi-signal environment, the biometric computing component 105 can differentiate between various audio signals or speakers based on recognition of homogenous voice data groups in the auditory environment, and identification of voice biometric profiles from the recognized homogenous voice data groups.

The biometric computing component 105 can also include a downloadable web application comprising ML methods that can be stored in memory on the user device 102. The ML methods can include algorithms for processing audio signals, audio signal data, homogenous voice data groups, acoustic characteristics, and metadata associated with the audio signal data and acoustic characteristics. The ML methods can be used to determine, isolate, differentiate, and/or extract the target audio signal 124A. In one configuration, the audio signals may be processed to extract a voice biometric profile as a unique encoding of a speaker's voice print. The voice biometric profile can be used to identify individual speakers (e.g., any one of, or combination of, speakers 124-126) of the speech signal. Each individual speaker 124-126 may include an audio signal associated with individual. For example, speaker 124 (e.g., the target speaker), may include a target audio signal 124A, while non-target speakers 125, 126 may include non-target audio signals 125A, 126A. Once a target speaker 124 is identified, the target speaker voice can be isolated using the ML methods. In such an example, the target speaker may produce a first homogenous voice data group that a first set of acoustic characteristics can be extracted from, and a first set of metadata can be associated to. The non-target speaker may produce a second homogenous voice data group that a second set of acoustic characteristics can be extracted from, and a second set of metadata can be associated to. A second non-target speaker may produce a third homogenous voice data group that a third set of acoustic characteristics can be extracted from, and a third set of metadata can be associated to.

Alternatively, the biometric computing component 105 may monitor for each audio signal produced by speakers 124-126, and may differentiate each audio signal from one another based on the acoustic characteristics of the audio signal captured by the user device 102. By differentiating speaker 124 from speakers 125, 126, the biometric computing component 105 may identify speaker 124 (if said speaker is intended as the target speaker) as the target speaker or any other speaker in the room as the target speaker, and subsequently filter out or suppress the audio signals relating to the other two speakers (although the other speakers do not have to be filtered out).

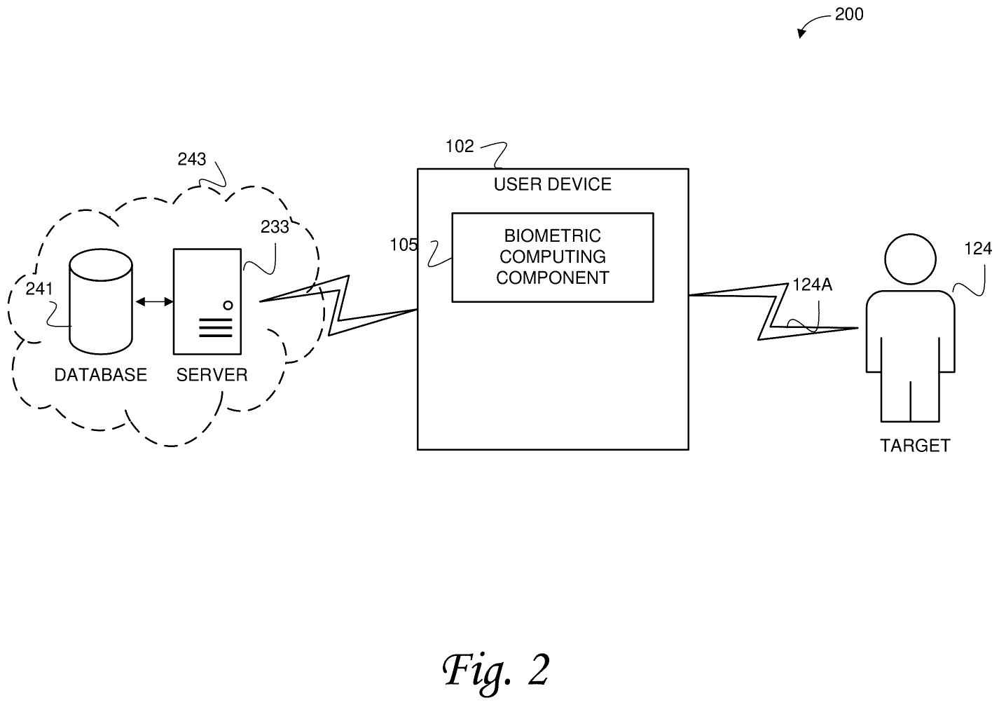

FIG. 2 illustrates an example configuration of a network environment of the biometric metadata system. The network environment 200 may include the user device 102, the target speaker 124, and the cloud server 243. As seen in FIG. 1, the plurality of audio signals 124A-126A may be received by the user device 102 and analyzed by the biometric computing component 105. As described in FIG. 1, the biometric computing component 105 can determine the target audio signal 124A associated with the target audio speaker or source 124 and analyze metadata associated with the target audio signal to isolate or differentiate the target audio signal 124A from the plurality of audio signals.

It should be noted that the biometric computing component is not limited to one specific method of biometric identification. For example, various voice recognition methods may be operable (e.g., text-independent recognition and text-dependent recognition methods), it is foreseeable that other voice recognition methods can be used to determine/identify a target audio signal from a plurality of audio signals. Here, the biometric computing component 105 may determine that the audio signal associated with speaker 124 is the target audio source 124. Once the effective audio extraction system determines a target audio source 124, the biometric computing component 105 can isolate and extract the target audio source 124 from the plurality of audio signals by continuing to match the voice biometric profile with the acoustic characteristics in the audio signal. In some embodiments, the described matching process may be done at discrete increments, for example, at distinct or dynamic audio frames. In further embodiments, the described matching process may be done by comparing metadata associated with acoustic characteristics.

In one configuration, the biometric computing component 105 may isolate the metadata associated with the target audio signal (i.e., the metadata associated with the digital signal) and extract the target audio signal from the plurality of audio signals. In one configuration, the biometric computing component may further remove and/or suppresses all, substantially all, or some other audio signals received by the biometric computing component. The target audio signal may then be transmitted to downline processes (e.g. the cloud server 243). Transmission of the audio signal is not limited to any specific method of signal transmission, and can include various signal processing methods that transmit digitized analog signals like the audio signal described herein. In one embodiment, the user device 102 may be configured to remove/prevent audio data not associated with the target audio source 124 from being transmitted to downline processes. For example, if a single target speaker is identified, once the voice biometric profile is matched with the target audio signal, all other audio signals may be suppressed.

In various embodiments, digital signal data associated with the extracted target audio signal can be compressed. Various data compression methods can be applied to compress the data associated with the target audio signal. For example, after isolating the target audio signal, the biometric computing component can compress the digital signal associated with the target audio signal. As discussed in further detail in FIGS. 2 and 3 disclosed herein, in some configurations, the digital signal can be compressed using a processor on the user device. The compressed digital signals can then be sent to a cloud server as analog signals. The cloud server may be configured to receive the analog signal and convert the analog signal to a digital signal. The digital signal can be stored in a database or decompressed. In such embodiments, acoustic characteristics can be extracted from the digital signal via the server or processor.

As seen in FIG. 2, the user device 102 may be communicatively connected to the server 233. Communicatively connected may include, for example, a wired or wireless network adapter or a wireless data transceiver for use with a mobile phone network, Global System for Mobile communications (GSM), 3G, or other mobile data network or Worldwide Interoperability for Microwave Access (WIMAX), or an 802.11 wireless network (WLAN). The server 233 may be a cloud server 243 disposed remotely to the user device 102. For example, the cloud server 243 can be hosted on a remote server farm. The cloud server 243 can include a database 241 configured to store data received by the cloud server 243. The stored data can include the extracted data associated with the target audio signal.

FIG. 3 illustrates an example configuration of the user device 102. The user device 102 can include, cellular telephones, smart phones, MP3 players and other media players, tablet computing devices, laptop and notebook computers, personal computers, two-way radios, hearing aids and assisted listening devices, and other devices for communicating or playing audio content. For example, systems and methods can be implemented with dedicated and multi-mode electronic devices including cell phones (including smart phones), two-way radios, tablet computers, PCs, speech-recording devices, and other devices for recording, capturing, playback or communicating speech. In some embodiments, the systems and methods described herein can be implemented as an application configured to run on a dedicated processor, a shared processor, or processors used by the device with which the application is implemented, or a combination thereof. In the case of an application (e.g., a program downloadable on a tablet or mobile phone) the application can be configured with the appropriate user interfaces to allow the user to control setpoints and features of the process to adjust the process for a particular environment, or to adjust the process to their liking. Additionally, in various embodiments, the application can be configured to sense various states of the device in which it is running, and to configure itself for operation in accordance with those states.

In embodiments, the user device 102 may include the biometric computing component 105, a memory 315, a processor 314, an analog to digital converter (ADC) 313, and an audio input 311. In the example embodiment, the user device 102 may include a processor 314 for executing instructions. Processor 314 may include processing units, for examples, a multi-core configuration. In some embodiments, executable instructions may be stored in the memory 315. Memory 315 can include any device allowing information such as executable instructions and/or written works to be stored and retrieved. Memory 315 may include computer readable media. Memory 315 can store, for example, computer readable instructions for receiving and processing audio input signals.

For software embodiments, various components (e.g., the biometric computing component) can be provided to perform the same or similar functions using software components running on a processor such as a general-purpose processor or a digital signal processor. Various ML methods can be used to isolate metadata associated with the audio signals. The various ML methods can include regression methods, classification methods, clustering methods, dimensionality reduction methods, ensemble methods, neural net and deep learning methods, transfer learning methods, reinforcement learning methods, natural language processing methods and word embedding methods. For example neural net and deep learning methods can include Random Forest, Gradient Boost, Extreme Gradient Boost.

As used herein, the term “component” can be a collection of software modules, hardware modules, software/hardware modules or any combination or permutation thereof. As another example, a tool can be a computing device or other appliance on which software runs or in which hardware is implemented. The component can describe a given unit of functionality that can be performed in accordance with embodiments of the present disclosure. As used herein, the component might be implemented utilizing various forms of hardware, software, or a combination thereof. For example, processors, controllers, DSPs, ASICS, PLAS, PALS, CPLDs, FPGAs, logical components, software routines or other mechanisms might be implemented to make up a module.

In implementation, the components described herein might be implemented as a discrete modules or as functions and features shared in part or in total among modules. In other words, as would be apparent to one of ordinary skill in the art after reading this description, the various features and functionality described herein may be implemented in various applications and can be implemented in separate or shared modules in various combinations and permutations. Even though various features or elements of functionality may be individually described or claimed as separate modules, one of ordinary skill in the art will understand that these features and functionality can be shared among common software and hardware elements, and such description shall not require or imply that separate hardware or software components are used to implement such features or functionality. Where components or modules of the invention are implemented in whole or in part using software, in one embodiment, these software elements can be implemented to operate with a computing or processing module capable of carrying out the functionality described with respect thereto. One such example component is shown in FIGS. 1-3 as the biometric computing component.

The user device 102 may also include a media output component 310 for presenting information to a user of the user device. Media output component 310 may be any component capable of conveying information to a user. For example, the media output component 310 can include a screen on a kiosk, a cell phone, personal computer, tablet etc. In some embodiments, media output component 310 may include an output adapter such as a video adapter and/or an audio adapter. An output adapter may be operatively coupled to processor 304 and operatively couplable to an output device such as a display device, a liquid crystal display (LCD), organic light emitting diode (OLED) display, or “electronic ink” display, or an audio output device, a speaker or headphones, or similar display devices.

The user device 102 may further include an audio input 311 for receiving input from audio sources (e.g., audio sources 124-126). The audio input 311 may include a microphone, or other audio receiver configured to receive sound waves. For example, the microphone could be a condenser microphone, dynamic microphone, piezoelectric microphone, or other microphone used to capture voice. Although not shown, the user device 102 may include, for example, a keyboard, a pointing device, a mouse, a stylus, a touch sensitive panel, a touch pad, a touch screen, a gyroscope, an accelerometer, a position detector, or an audio input device. The user device 102 may further include a touch screen that may function as both an output and input of the user device 102. The user device 102 may also include a communication interface, which may be communicatively connected to cloud server 243. As seen further in FIG. 3, the user device 102 may include an ADC 313 configured to convert a sound wave from an analog signal to a digital signal. The ADC 313 may include any component configured to convert an analog audio signal to a digital audio signal. Once the ADC 313 converts the analog audio signals to the digital audio signal, the digital audio signal may be separated into various acoustic characteristics.

The user device 102 may also include a user interface that may include, among other possibilities, a web browser and client application. Web browsers enable users, such as speaker 124 to display and interact with media and other information typically embedded on a web page or a website. In one configuration, the application allows users of the user device to interact with a server (e.g., server 233). The application may include a web application hosted on a cloud server 243, the web application accessed via the application, or web browser of the user device 102.

In some embodiments, enhanced file size compression can be accomplished in conjunction with the multichannel processing described herein. For example, in some embodiments the multichannel processing can be applied to enhance an audio file that has already been compressed using a compression standard such as, for example, MP3. After applying the multichannel processing described herein, the file can then be compressed again using a compression algorithm (e.g., MP3 again). Because the multichannel processing described herein can enhance the sound without adding data back into the system, the content can tolerate the second compression without undue loss.

In various embodiments, the audio processing techniques discussed herein can be applied to a file (whether or not already compressed) to enhance the digital signal. However, in further embodiments, the processing techniques can be applied in such a manner so as to compensate for anticipated compression in advance of the file being compressed. Accordingly, for example, if it is known that a compression algorithm to be applied tends to have a greater adverse effect on a the isolated metadata, the processing that might otherwise be applied can be increased for that particular frequency band or bands to compensate for the anticipated effects of the compression. Accordingly, even if the file being processed according to the systems and methods set forth herein was previously compressed, the processing can not only help to compensate for the prior compression, but it can also be implemented to overcompensate in anticipation of further compression.

In other embodiments, such as applications where speech is captured by a person talking on a cellular telephone or other like device, the process can be implemented to remove metadata not associated with the target audio signal (i.e., the person talking). Such embodiments can be beneficial in various speech applications including cellular telephony applications where a user typically is speaking with his or her mouth in close proximity to the microphone. In such applications, the voice signal tends to have a higher energy than the background noise due to the proximity of the source to the microphone.

The audio signals described herein can be captured instantaneously, or over a given time interval. Looking at an average audio signal over a predetermined time interval may provide the benefit of not triggering metadata manipulation for sporadic audio bursts of background noise, while allowing metadata isolation of an ongoing audio signal (e.g., an ongoing stream of speech). Additionally, detecting gaps in speech, such as by detecting metadata not associated with the target speaker, can allow the system to cut out the microphone's vox or ‘mute’ the microphone. In this way, for example, when a first caller is listening to another caller and not talking, background noise in the first caller's environment will not interfere with the call.

The audio signal may be carried by a sound wave and may be received by an audio receiver, such as a microphone. The audio signal may be an electro-magnetic signal, such as a radio-frequency signal, infrared signal, microwave signal, optical signal, or other information carrying wave. In such embodiments, the audio signal may be received by an electro-magnetic detector or antenna, such as a radio frequency receiver, optical receiver, microwave antenna, or other electronic receiver as known in the art. The audio signal may be a multi-band signal, e.g., that carries multiple frequency bands, including background noise, voice frequency bands, and other sounds such as music. The user device can include a number of devices including, for example, cellular telephones, smart phones, MP3 players and other media players, tablet computing devices, laptop and notebook computers, personal computers, two-way radios, hearing aids and assisted listening devices, and other devices for communicating or playing audio content.

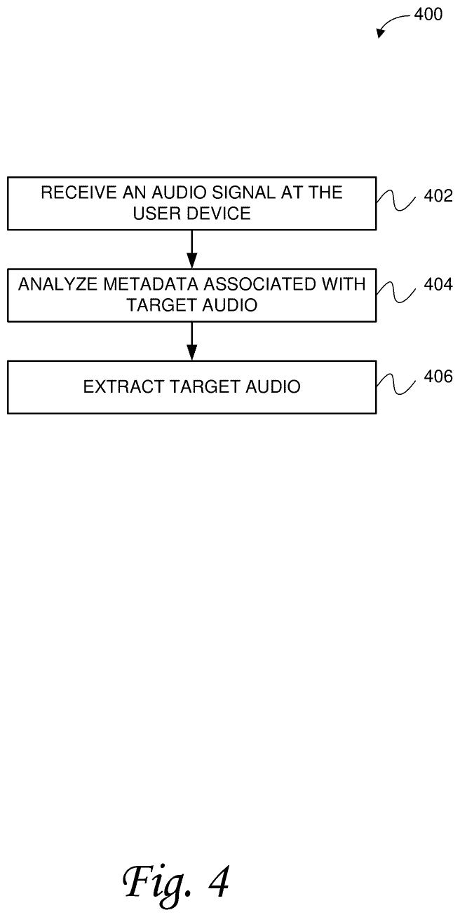

FIG. 4 is an illustration of an example method of isolating audio content via biometrically identifying metadata associated with a target audio signal. The method 400 includes receiving audio content at a user device, analyzing metadata associated with the target audio signal, the metadata associated with the target audio signal comprising biometric metadata, and extracting and/or isolating the target audio signal by extracting and/or isolating the metadata associated with the target audio signal.

At activity 402, the method 400 may include receiving an audio signal at the user device, where the audio signal may include a homogenous voice data group. Once the analog audio signal is received at the user device, the analog audio signal may be transmitted to an analog to digital converter (ADC) to convert the analog audio signal to a digital audio signal. The ADC can generate a digital audio signal for each analog audio signal received by the user device. For example, the user device may be configured to receive a first sound wave comprising a first analog audio signal on a first channel and a second sound wave comprising a second analog audio signal on a second channel (in for example, a two-channel embodiment). In such an example, the ADC may convert the first analog audio signal to a first digital audio signal, and convert the second analog audio signal to a second digital audio signal. After the audio signal has been converted from an analog audio signal to a digital audio signal, the biometric computing component 105 may extract acoustic characteristics from each digital audio signal. The biometric computing component can then associate metadata to the determined acoustic characteristics of each digital audio signal. In other words, each digital audio signal can be represented by a set of metadata, where said metadata is representative of certain acoustic characteristics determined from the digital audio signal. The sets of metadata can then be associated with a voice biometric profile to isolate certain aspects of the audio signals into different discrete speakers. The biometric computing component can then differentiate and/or categorize the sets of metadata to separate the target audio signal from the plurality of audio signals. Thus, using the methods described herein, the user device 102 via the biometric computing component 105 can determine the target audio signal through the extrapolation and differentiation of metadata.

In various embodiments, determination of the target signal may include a biometric authentication method. The biometric authentication method may include receiving known voice biometric profiles from a data store, memory, server, or similar data storage feature, and identifying the individual speaker of a particular speech signal (i.e., a homogenous voice data group) by matching the voice biometric profile extracted from the audio signal to one of the voice biometric profile. As discussed, the voice biometric profile may include a set of metadata representative of acoustic characteristics of the speaker's voice or homogenous voice data group. As such, to match the known voice biometric profile with the present audio signal speaker, the biometric authentication method may compare the known metadata (i.e., known voice biometric profile) with the metadata determined from biometric computing component of the active speaker (from the target audio signal). In this way, for example, individuals talking in a crowded room may be identified from a single audio signal collected from that room using an electronic listening device such as a microphone, as the audio signals for each speaker may be broken down into metadata associated with the acoustic characteristics of each speaker's voice or homogenous voice data group, separated based on metadata grouping, and then matched with stored profiles of metadata or a voice biometric profile. Individual voices or homogenous voice data groups may then be parsed from the audio signal and enhanced using the voice biometric profile for each individual speaker (whether or not the voice profile key had previously been stored in a data storage feature). This process may be repeated for multiple individual speaker in a single audio signal.

Determining the target audio signal may further include extracting a voice biometric profile to identify an individual speaker of the speech signal or homogenous voice data group or differentiate between speakers in the same audio signal. For example, such biometric identification may be used to authenticate an individual for various purposes, including as a biometric password for granting physical or electronic access requests. The profile key may be stored in a memory (e.g., memory 315) configured to store historical voice biometric profile, each voice biometric profile corresponding to an individual.

At activity 404, the method 400 may include analyzing metadata associated with the plurality of audio signals to determine metadata associated with the target audio signal. Here, the biometric computing component 105 may monitor the digital audio signal to extract acoustic characteristics, from which metadata is associated. The metadata may then be separated into voice biometric profiles, i.e., a first voice biometric profile of a first speaker and a second voice biometric profile of a second speaker. These voice biometric profiles may allow for the biometric computing component to isolate the voice biometric profile or metadata associated with the target speaker in the audio signal, since each digital signal is associated with an analog signal received at the audio input 311 of the user device 102.

At activity 406, the method 400 may include extracting target audio. The biometric component can include software downloaded to and stored on the user device. The software may include instructions stored in memory on the user device for ML methods to filter various features of the received audio signal. For example, in one configuration, the instructions may include ML methods configured to isolate and extract metadata associated with a specific audio signal. The metadata pointing to digital data associated with the specific audio signal or speaker.

The process can be implemented so as to filter out background noise, limit loudness (or over modulation from a voice), “expand” the voice and overall sound, and apply broadcast audio techniques that will make a voice sound better, clearer and crisper, which enables transmission in a very narrow field. In other words, the ML may utilize the metadata associated with a voice biometric profile to filter audio signals that are outside of the voice profile out of the digital audio signal, i.e., non-target voice or noise may be removed from the audio signal based on the target voice profile being identified.

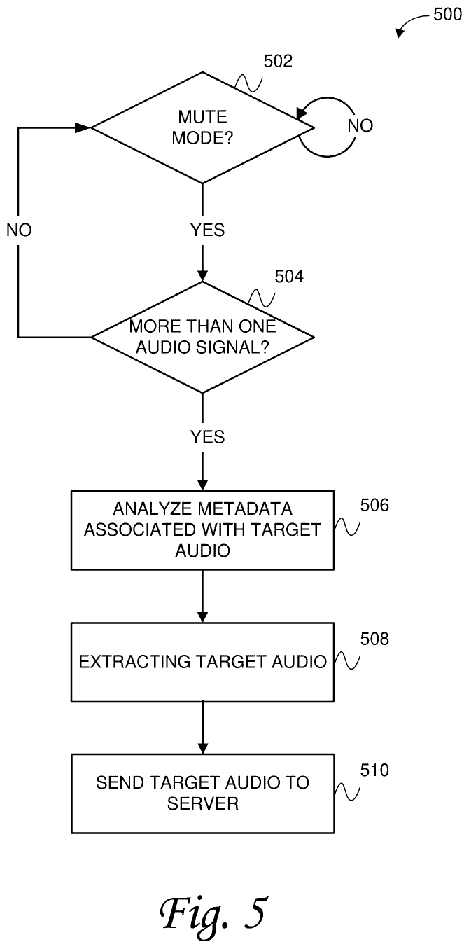

FIG. 5 illustrates an example of a method for extracting audio in accordance with various embodiments of the systems and methods described herein. The method 500 may include determining that the user device is in a mute mode, that audio signals are received as inputs to the user device, analyzing the plurality of audio signals to determine a target audio signal, extracting the target audio signal from the plurality of audio signals, and transmitting the target audio signal to a server.

At activity 502, the method may include determining that the user device 102 is in a mute mode. Although this example discloses a mute mode, the user device 102 may also be in other modes that require isolation and extraction of a target audio signal. For example, the user device may include a speak through mode, the speak through mode being an audible input in place of a click through for certain applications (e.g., web apps, pop-up advertisements, etc.). For purposes of the example disclosed in FIG. 5, once the effective audio extraction determines that the user device 102 is in a mute mode, the effective audio extraction system progresses to activity 504.

At activity 504, the method may include determining whether the user device 102 has received more than one signal. If the user device 102 has received only one signal, then the biometric computing component 105 may not be required to isolate and extract the target audio. In other words, if the audio signal only includes one speaker and no noise, there is no need to differentiate between speakers or filter our/enhance voices or background noise. However, if the user device 102 receives more than one signal, then the biometric computing component 105 may isolate the target audio signal according to activity 504. It is foreseeable that in some configurations, the effective audio extraction system may continuously monitor/receive audio signals from a plurality of audio signals. By determining a target audio signal from a target audio source, the biometric computing component can selectively engage in the mute or unmute mode described in activity 502. For example, the effective audio extraction system 100 may unmute the device when a target speaker is speaking and mute the device when the target speaker is not speaking. By muting and unmuting the user device, the effective audio extraction system 100 can provide an alternative form of signal isolation. For example, instead of determining a target signal and isolating and extracting the target signal, the effective audio extraction system 100 can determine whether the target speaker of the target signal is generating a target audio signal, and then isolate the plurality of audio signals not associated with the speaker once the speaker begins to speak (i.e., a wait and see mode, wherein the device is listening for whether the speaker is speaking or not, and extracting audio only when the speaker is speaking).

At activity 506 and 508, the method 500 may include analyzing metadata associated with the plurality of audio signals to determine metadata associated with the target audio signal according to activity 404 and extracting target audio according to activity 406 described in FIG. 4 above. It should be noted that in some configurations it may not be necessary for the biometric computing component to isolate the target audio signal before extraction. For example, it is foreseeable that the biometric computing component may only need to determine the target audio signal before extracting the audio signal.

At activity 510 the method 500 may include transmitting the extracted audio signal to a server. Once the effective audio extraction system determines a target audio source 124, the biometric computing component 105 may isolate, differentiate, and extract the target audio source 124 from the plurality of audio signals. The target audio signal may then be transmitted to downline processes (e.g. the cloud server 243). In one embodiment, the user device 102 may be configured to remove/prevent audio data not associated with the target audio source 124 to be transmitted to downline processes. In one embodiment, digital signal data associated with the extracted target audio signal can be compressed. The compressed digital signal can then be sent to a cloud server as an analog signal. The cloud server may be configured to receive the analog signal and convert the analog signal to a digital signal. The digital signal can be stored in a database or decompressed.

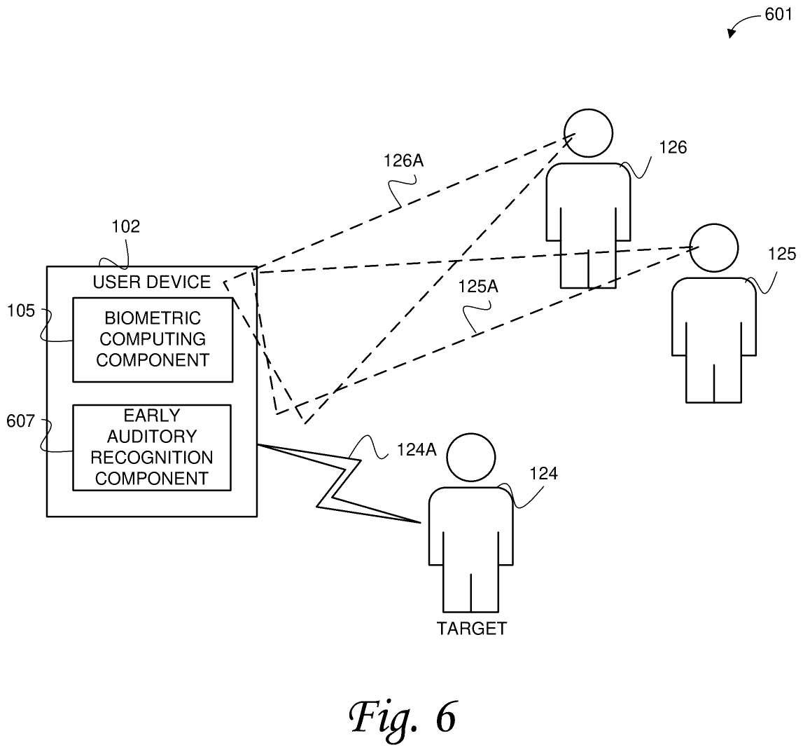

FIG. 6 is an illustration of an example environment 601 in which the effective audio extraction system may be applied, according to various embodiments. In such embodiments, the effective audio extraction system 100 may further include an early auditory recognition (EAR) component 607. The EAR component 607 may be configured to determine the direction and distance of audio signals (e.g., audio signals 124A, 125A and 126A). For example, the user device 102 may be configured to monitor individual speakers in a multi-speaker environment. By monitoring each audio signal in a multi-signal environment, the user device 102 can determine and isolate a target audio signal 124A associated with a target speaker 124 (i.e., an individual speaker). In addition to determining and isolating the target audio signal 124A associated a target speaker 124, the user device 102 via the EAR component 607 can determine the initial direction of the target audio signal 124A and the distance of the target audio signal 124A.

In one embodiment, the EAR component 607 may determine the initial direction and distance of the target audio signal 124A by forming a beam in the anticipated direction of the targeted voice. The EAR component 607 may then apply voice activity detection (VAD) to the beam. If no voice is detected, the EAR component 607 may progress to the next instance of an audio signal (e.g., the EAR component 607 will progress to a different audio signal). If the EAR component 607 detects a voice, then the EAR component 607 may refine the beam based on the distance and direction of the targeted voice.

Furthermore, in some configurations, the EAR component 607 may separate voices in the beam by range filtering audio signals based on their signal characteristics. For example, the EAR component 607 can separate the voices in the beam by range filtering the voices using loudness and reverberation of each voice. Once the EAR component 607 determines the direction and distance of each audio signal, the biometric computing component 105 may detect/determine the signal characteristics of each audio signal within the beam according to the methods disclosed herein. For example, the user device 102 via the biometric computing component 105 can detect acoustic, biometric and/or linguistic biomarkers for each range-filtered signal. In one configuration, once the EAR component 607 determines the direction and distance of the target audio signal 124A, the biometric computing component 105 can detect/determine the signal characteristics of the target audio signal 124A. The user device 102 via the biometric computing component 105 can determine/isolate/extract the target audio source 124 on edge using the methods disclosed herein (by determining/isolating/extracting the metadata of the target audio signal).

For the purposes of the disclosure herein, the distance of the target audio signal 124A can be defined as the geographic distance in space between the source of the target audio signal 124A (e.g. the target speaker 124) and the user device 102 (e.g., a determination that the target audio source 124 is about 1 ft, or about ½ ft away from the user device). In addition, the direction of the target audio signal 124A can be defined as a the geographic location of the target audio signal source in respect to the user device 102. For example, the user device 102 via the EAR component 607 may determine that the target speaker 124 is positioned 120 degrees from the user device 102. The degrees and angles being referenced from a plane extending outwardly from about the center of the user device 102.

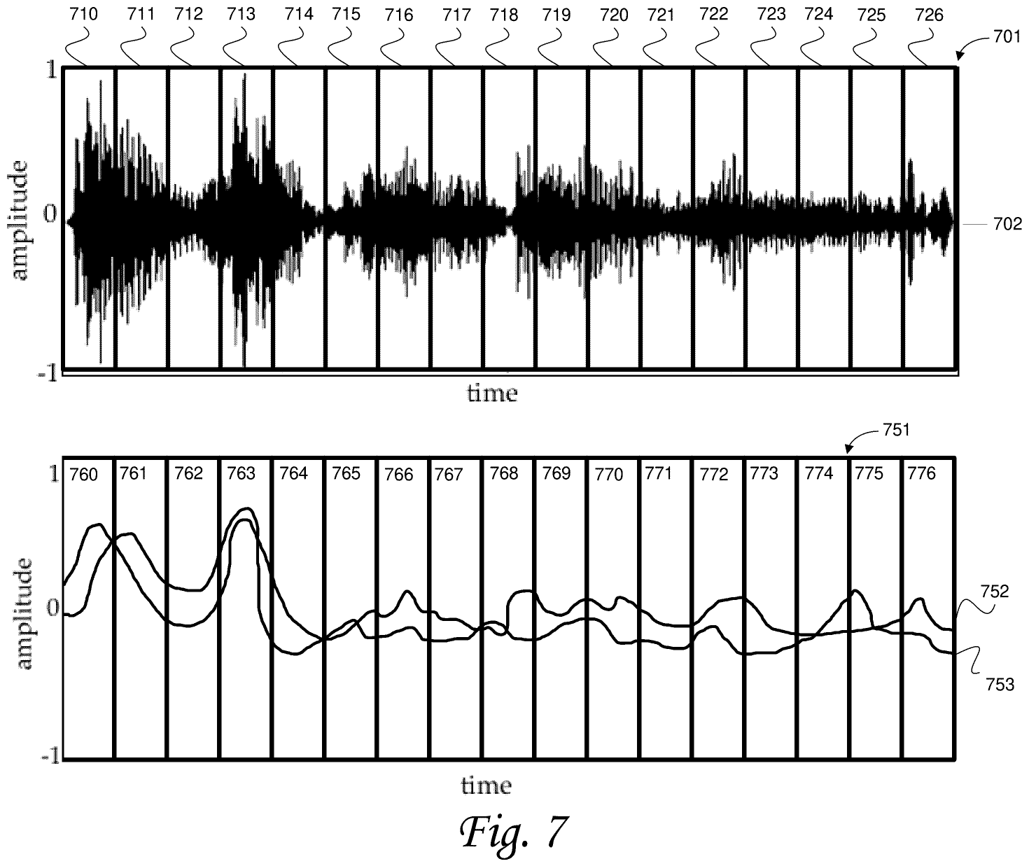

Referring now to FIG. 7, FIG. 7 is an example graphical illustration of audio signals separated by audio frame, according to various embodiments disclosed herein. Exemplary graph 701 depicts an example audio signal 702 as measured by the acoustic characteristic of amplitude over time. The audio signal 702 may be broken down into audio frames 710-726. Each audio frame 710-726 separates the audio signal 702 into a discrete time period. Such time periods can range from 0.1 ms to 1 second, and can be adjusted to account for precision in the system. For example, a system that can make more dynamic changes to voice isolation or identification, may include shorter audio frames (e.g., 100 ms) to allow for faster assumptions about speakers to be made or for faster changes to the auditory environment to be captured. In a different example, if an auditory environment is measured over longer periods of time, it may be sufficient to break audio frames into larger time periods (e.g., 1 second).

The acoustic characteristic extracted from the audio signal 702 can be associated with metadata, for example as depicted in 751, where the audio signal 702 is represented as a single data point over time 752. This data point over time 752 can be separated into metadata audio frames 760-776. The metadata audio frames 760-776 may be compared from a first audio signal 752 to a second audio signal 753 to determine a second homogenous voice data group or speaker is present in the audio signal. By comparing similar acoustic characteristics by frame, the present disclosure can differentiate speakers. For example, at metadata audio frame 760 the amplitude of the audio signals are different despite the signals being present in the same discrete audio frame or time. This could provide the initial assumption that two homogenous voice data groups or speakers are present in the audio signal. In such an example, this assumption could be confirmed (i.e., the confidence score is increased past a threshold amount), by looking to the following audio frame 761, which still includes two distinct metadata sets representative of different amplitudes (i.e., acoustic characteristics indicative of two speakers). This can be confirmed by looking to the further audio frames 762-776. The audio frames depicted in these graphs 701, 751 are merely exemplary and one skilled in the art would understand that more audio frames may exist (i.e., audio frame may be present throughout the audio signal) and that other acoustic characteristics may be compared to determine whether multiple homogenous voice data groups exist in an audio signal.

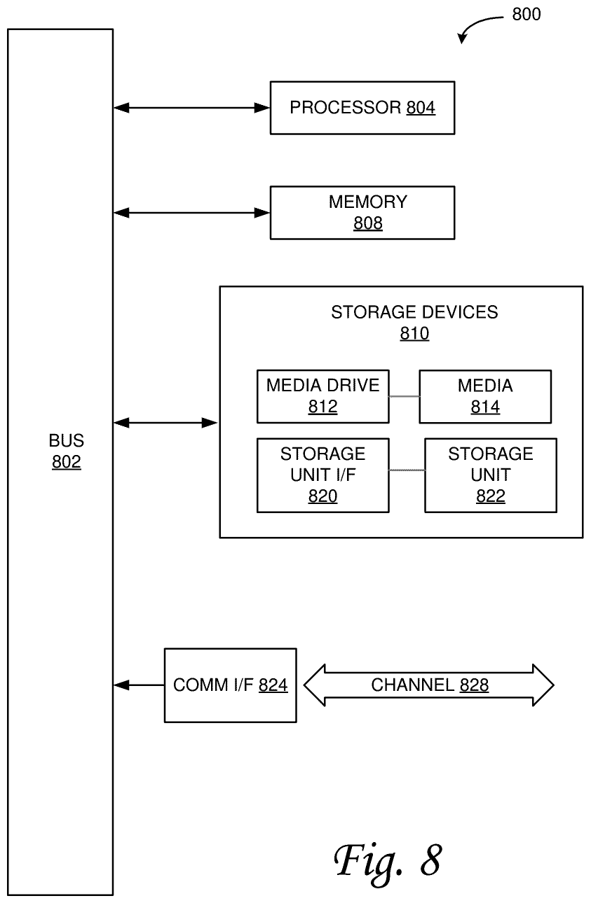

Referring now to FIG. 8, computing module 800 may represent, for example, computing or processing capabilities found within desktop, laptop and notebook computers; hand-held computing devices (PDA's, smart phones, cell phones, palmtops, etc.); mainframes, supercomputers, workstations or servers; or any other type of special-purpose or general-purpose computing devices as may be desirable or appropriate for a given application or environment. Computing module 800 might also represent computing capabilities embedded within or otherwise available to a given device. For example, a computing module might be found in other electronic devices such as, for example, digital cameras, navigation systems, cellular telephones, portable computing devices, modems, routers, WAPs, terminals and other electronic devices that might include some form of processing capability.

Computing module 800 might include, for example, processors, controllers, control modules, or other processing devices, such as a processor 804. Processor 804 might be implemented using a general-purpose or special-purpose processing engine such as, for example, a microprocessor, controller, or other control logic. In the illustrated example, processor 804 is connected to a bus 802, although any communication medium can be used to facilitate interaction with other components of computing module 800 or to communicate externally.

Computing module 800 might also include memory modules, simply referred to herein as main memory 808. For example, preferably random access memory (RAM) or other dynamic memory might be used for storing information and instructions to be executed by processor 804. Main memory 808 might also be used for storing temporary variables or other intermediate information during execution of instructions to be executed by processor 804. Computing module 800 might likewise include a read only memory (“ROM”) or other static storage device coupled to bus 802 for storing static information and instructions for processor 804.

The computing module 800 might also include various forms of information storage mechanism 810, which might include, for example, a media drive 812 and a storage unit interface 820. The media drive 812 might include a drive or other mechanism to support fixed or removable storage media 814. For example, a hard disk drive, a floppy disk drive, a magnetic tape drive, an optical disk drive, a CD or DVD drive (R or RW), or other removable or fixed media drive might be provided. Accordingly, storage media 814 might include, for example, a hard disk, a floppy disk, magnetic tape, cartridge, optical disk, a CD or DVD, or other fixed or removable medium that is read by, written to or accessed by media drive 812. As these examples illustrate, the storage media 814 can include a computer usable storage medium having stored therein computer software or data.

In alternative embodiments, information storage mechanism 810 might include other similar instrumentalities for allowing computer programs or other instructions or data to be loaded into computing module 800. Such instrumentalities might include, for example, a fixed or removable storage unit 822 and storage unit interface 820. Examples of such storage units 822 and storage unit interfaces 820 can include a program cartridge and cartridge interface, a removable memory (for example, a flash memory or other removable memory module) and memory slot, a PCMCIA slot and card, and other fixed or removable storage units 822 and storage unit interfaces 820 that allow software and data to be transferred from the storage unit 822 to computing module 800.

Computing module 800 might also include a communications interface 824. Communications interface 824 might be used to allow software and data to be transferred between computing module 800 and external devices. Examples of communications interface 824 might include a modem or softmodem, a network interface (such as an Ethernet, network interface card, WiMedia, IEEE 802.XX or other interface), a communications port (such as for example, a USB port, IR port, RS232 port Bluetooth® interface, or other port), or other communications interface. Software and data transferred via communications interface 824 might typically be carried on signals, which can be electronic, electromagnetic (which includes optical) or other signals capable of being exchanged by a given communications interface 824. These signals might be provided to communications interface 824 via a channel 828. This channel 828 might carry signals and might be implemented using a wired or wireless communication medium. Some examples of a channel might include a phone line, a cellular link, an RF link, an optical link, a network interface, a local or wide area network, and other wired or wireless communications channels.

In this document, the terms “computer program medium” and “computer usable medium” are used to generally refer to media such as, for example, memory 808, storage unit 820, media 814, and channel 828. These and other various forms of computer program media or computer usable media may be involved in carrying sequences of instructions to a processing device for execution. Such instructions embodied on the medium, are generally referred to as “computer program code” or a “computer program product” (which may be grouped in the form of computer programs or other groupings). When executed, such instructions might enable the computing module 800 to perform features or functions of the present invention as discussed herein.

While various embodiments of the present invention have been described above, it should be understood that they have been presented by way of example only, and not of limitation. Likewise, the various diagrams may depict an example architectural or other configuration for the invention, which is done to aid in understanding the features and functionality that can be included in the invention. The invention is not restricted to the illustrated example architectures or configurations, but the desired features can be implemented using a variety of alternative architectures and configurations. Indeed, it will be apparent to one of skill in the art how alternative functional, logical or physical partitioning and configurations can be implemented to implement the desired features of the present invention. Also, a multitude of different constituent module names other than those depicted herein can be applied to the various partitions. Additionally, with regard to flow diagrams, operational descriptions and method claims, the order in which the steps are presented herein shall not mandate that various embodiments be implemented to perform the recited functionality in the same order unless the context dictates otherwise.

Although the invention is described above in terms of various exemplary embodiments and implementations, it should be understood that the various features, aspects and functionality described in the individual embodiments are not limited in their applicability to the particular embodiment with which they are described, but instead can be applied, alone or in various combinations, to the other embodiments of the invention, whether or not such embodiments are described and whether or not such features are presented as being a part of a described embodiment. Thus, the breadth and scope of the present invention should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent. The use of the term “module” does not imply that the components or functionality described or claimed as part of the module are all configured in a common package. Indeed, any or all of the various components of a module, whether control logic or other components, can be combined in a single package or separately maintained and can further be distributed in multiple groupings or packages or across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

1. A method of voice isolation, comprising:
receiving a plurality of audio signals comprising a homogeneous voice data group;
extracting a first set of acoustic characteristics from the plurality of audio signals;
associating a first set of metadata with the first set of acoustic characteristics; and
creating a voice biometric profile for the homogeneous voice data group, wherein the voice biometric profile comprises the first set of metadata associated with the homogenous voice data group.

2. The method of claim 1, further comprising:
identifying a target audio signal from the plurality of audio signals based on the voice biometric profile.

3. The method of claim 1, further comprising:
enhancing audio signals with the first set of acoustic characteristics; and
suppressing audio signals not associated with the first set of acoustic characteristics.

4. The method of claim 1, further comprising:
receiving the plurality of audio signals comprising a second homogenous voice data group;
extracting a second set of acoustic characteristics from the plurality of audio signals;
associating a second set of metadata with the second set of acoustic characteristics; and
creating a second voice biometric profile for the second homogenous voice data group, wherein the second voice biometric profile comprises the second set of metadata associated with the second homogenous voice data group.

5. The method of claim 4, further comprising:
differentiating the second voice biometric profile from the voice biometric profile by comparing the second set of metadata to the first set of metadata; and
isolating audio signals associated with the first voice biometric profile.

6. The method of claim 1, further comprising:
receiving the plurality of audio signals comprising a third homogenous voice data group;
extracting a third set of acoustic characteristics from the plurality of audio signals;
associating a third set of metadata with the third set of acoustic characteristics; and
creating a third voice biometric profile for the third homogenous voice data group, wherein the third voice biometric profile comprises the third set of metadata associated with the third homogenous voice data group.

7. The method of claim 6, further comprising:
differentiating the voice biometric profile from the second and third voice biometric profiles by comparing the first set of metadata to the second and third sets of metadata; and
isolating audio signals associated with the first voice biometric profile.

8. The method of claim 1, wherein the voice biometric profile uniquely identifies a target speaker.

9. The method of claim 1, further comprising converting each audio signal of the plurality of audio signals to a digital signal via an analog-to digital converter, the digital signal comprising acoustic characteristics extracted from each of the plurality of audio signals.

10. The method of claim 3, wherein suppressing audio signals not associated with the first set of acoustic characteristics includes removing metadata not associated with a target voice biometric profile.

11. The method of claim 10, wherein removing metadata not associated with the target voice biometric profile comprises filtering audio signals filtering audio signals not associated with the voice biometric profile.

12. The method of claim 1, wherein a target audio signal is isolated from the plurality of audio signals via a machine learning method stored in a memory of a user device, the machine learning methods configured to isolate the homogenous voice data group associated with target audio signal.

13. A system for voice differentiation, comprising:
an audio receiver configured to receive an analog audio signal;
an analog-to-digital converter configured to convert the analog audio signal received by the audio receiver to a digital audio signal; and
a biometric computing component, comprising: a processor and a non-transitory computer readable medium with computer executable instructions embedded thereon, the computer executable instructions configured to cause the processor to:
extract acoustic characteristics from the digital audio signal;
associate metadata to the extracted acoustic characteristics;
group the metadata into a first voice biometric profile if a first homogenous voice data group is detected in the digital audio signal;
differentiate the first voice biometric profile from a second voice biometric profile if two homogenous voice data groups are detected in the digital audio signal; and
suppress audio signal not associated with the first voice biometric profile.

14. The system of claim 13, wherein the two homogenous voice data groups comprises the first homogenous voice data group and a second homogenous voice data group.

15. The system of claim 14, further comprising:
a third voice biometric profile, if three homogenous voice data groups are detected in the digital audio signal, wherein the three homogenous voice data groups include the first homogenous voice data group, the second homogenous voice data group, and a third homogenous voice data group.

16. The system of claim 15, wherein the biometric computing component is further configured to cause the processor to differentiate the first biometric profile from the second and third biometric profiles; and
suppress the audio associated with the second and third voice biometric profiles.

17. The system of claim 13, wherein the acoustic characteristics are extracted from the digital audio signal at discrete audio frames.

18. The system of claim 13, wherein the computer executable instructions are further configured to cause the processor to isolate the metadata associated with a homogenous voice data group to create a voice biometric profile.

19. The system of claim 18, wherein the computer executable instructions are further configured to isolate the metadata associated with a homogenous voice data group via their voice biometric profile from a plurality of audio signals.

20. The system of claim 13, wherein the computer executable instructions are further configured to filter metadata not associated with a target voice biometric profile.

21. The system of claim 13, wherein the computer executable instructions are further configured to cause the processor to enhance an audio signal associated with the first homogenous voice data group by differentiating audio associated with the voice biometric profile of the first homogenous voice data group from audio associated with voice biometric profiles of the second homogenous voice data group.

22. The system of claim 13, further comprising a transceiver communicatively coupled to a server, wherein the server comprises a plurality of known voice biometric profiles, and wherein the system for voice differentiation identifies a target homogenous voice data group by transmitting a voice biometric profile to the server, matching the transmitted voice biometric profile with a known voice biometric profile, and transmitting an identification of the target homogenous voice data group to the system for voice differentiation from the server.

23. A method for differentiating a target audio signal from a plurality of audio signals, the method comprising:
receiving a plurality of audio signals via an audio input device;
extracting acoustic characteristics from each audio signal of the plurality of audio signals;
associating each acoustic characteristic to a set of metadata;
grouping each set of metadata with other sets of metadata representative of the target audio signal; and
differentiating metadata associated with the target audio signal from metadata associated with remaining plurality of audio signals.

24. The method of claim 23, wherein the target audio signal includes a homogenous voice data group, wherein the homogenous voice data group comprises acoustic characteristics, and wherein the acoustic characteristics are associated with a set of metadata that is grouped into a voice biometric profile that uniquely identifies a target speaker.

25. The method of claim 24, wherein the plurality of audio signals includes a first homogenous voice data group and a second homogenous voice data group, wherein each homogenous voice data group comprises unique and different acoustic characteristics that can be represented by metadata, and wherein the acoustic characteristics extracted from each homogenous voice data group are grouped into a voice biometric profile that identifies each speaker as a different homogenous voice data group.
